(19) United States
(12) Patent Application Publication
(10) Pub. No.: US 2023/0396231 A1
(43) Pub. Date: Dec. 7, 2023

(54) COMPOSITE WAFER AND METHOD FOR PRODUCING SAME

(71) Applicant: Shin-Etsu Chemical Co., Ltd., Tokyo (JP)

(72) Inventor: Shoji AKIYAMA, Gunma (JP)

(21) Appl. No.: 18/450,431

(22) Filed: Aug. 16, 2023

Related U.S. Application Data
(63) Continuation of application No. PCT/JP2022/004806, filed on Feb. 8, 2022.

(30) Foreign Application Priority Data
Feb. 19, 2021 (JP) 2021-025398

(51) Int. Cl. H03H 9/02; H03H 3/08

(52) U.S. Cl. CPC H03H 9/02574; H03H 3/08; H03H 9/02559

(57) ABSTRACT

To provide a method for producing a composite wafer including preparing a supporting substrate which is either lithium tantalate or lithium niobate and is substantially not polarized, preparing an active substrate which is either lithium tantalate or lithium niobate stuck on one surface side of the supporting substrate and is polarized, generating an interface by implanting an ion into the active substrate, sticking the supporting substrate and the active substrate, raising temperatures of the supporting substrate and the active substrate which are stuck to each other, and delaminating the active substrate at the interface. In addition, the composite wafer is provided.

The contents of the following patent application(s) are incorporated herein by reference:
NO. 2021-025398 filed in JP on Feb. 19, 2021
NO. PCT/JP2022/004806 filed in WO on Feb. 8, 2022

### BACKGROUND

### 1. Technical Field

The present invention relates to a composite wafer and a method for producing the same.

### 2. Related Art

A method of sticking a wafer of lithium tantalate (Lithium Tantalate: may be abbreviated to LT) into which a hydrogen ion is implanted in advance and a wafer of lithium tantalate via a metal film, and performing a thermal treatment, thereby causing delamination with heat while avoiding a problem due to a difference in thermal expansion coefficients, has been known (for example, see Non-Patent Document 1).

### PRIOR ART DOCUMENT

### Non-Patent Document

Non-Patent Document 1: “3-inch single crystal LiTaO3 films onto metallic electrode using SmartCut™ technology” Tauzin et al. ELECTRIC LETTERS, 19th June 2008, Vol. 44 No. 13

### Problem to be Solved

When lithium tantalate or lithium niobate (Lithium Niobate: may be abbreviated to LN) is used for a supporting wafer, a charge is generated also in a thin film LT or LN which is an active layer in accordance with polarization possessed by LT or LN as the supporting wafer, and thus characteristics are negatively affected.

### BRIEF DESCRIPTION OF THE DRAWINGS

FIG. 1 schematically illustrates a cross-sectional view of a composite wafer 10 according to the present embodiment.

FIG. 2 schematically illustrates each step of a method for producing the composite wafer 10.

FIG. 3 illustrates a relationship between a supporting substrate and a destruction temperature.

FIG. 4 illustrates a relationship between the supporting substrate and a Qmax value.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

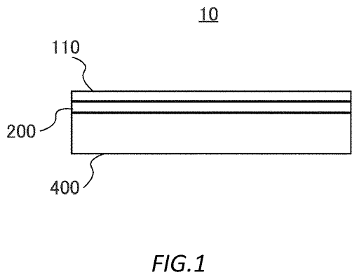

FIG. 1 schematically illustrates a cross-sectional view of a composite wafer 10 according to the present embodiment. The composite wafer 10 includes an LT substrate 400 as a supporting substrate, an interposed layer 200 which is disposed on one surface of the LT substrate 400, and an LT layer 110 as an active layer which is disposed on an opposite surface of the interposed layer 200 from the LT substrate 400.

The LT layer 110 is polarized. For example, the LT layer 110 is a single crystal, and is electrically polarized in a Z-axis direction of the crystal even without an external electric field. In this manner, the LT layer 110 is formed as an active layer which exerts a function such as a piezoelectric effect.

The LT layer 110 has a thickness of several hundred nm, for example. An LN layer may be used instead of the LT layer 110.

On the other hand, the LT substrate 400 is not substantially polarized. A state of not being substantially polarized herein is weaker than at least the polarization of the LT layer 110, and it includes not only a state in which polarization is not caused at all when there is no external electric field, but also a state in which polarization is not intentionally caused but was originally caused, a state in which polarization is remained even after going through a process of eliminating the polarization, a state in which polarization is caused in a level that does not affect exertion of the function of the LT layer 110, and the like. Furthermore, for example, the polarization of the LT substrate 400 is preferably 0.5 pC/N or less in an absolute value of a d33 meter.

The LT substrate 400 has a thickness of several hundred μm, for example, and it gives a mechanical strength when handling the composite wafer 10. Instead of the LT substrate 400, another substrate having a little difference in expansion coefficients from an active layer, for example, an LN substrate may be used.

The interposed layer 200 is disposed between the LT layer 110 and the LT substrate 400 in a thickness direction. The interposed layer 200 preferably has insulation properties, and is preferably easy to process, for example, easy to make a mirror surface with polishing. The interposed layer 200 may be at least one of SiO₂, SiON, or SiN. The interposed layer 200 is not polarized in a state where external voltage has not been applied.

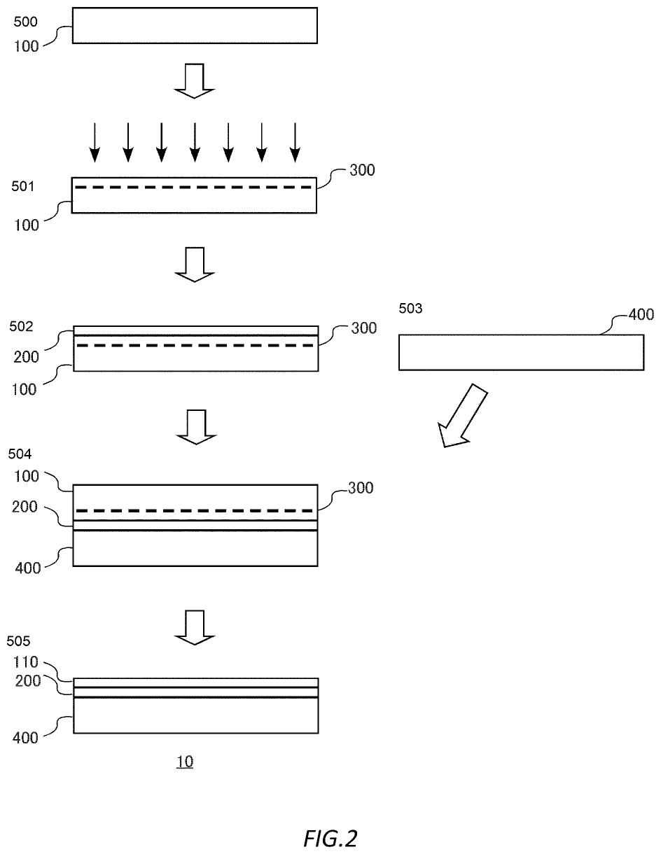

FIG. 2 schematically illustrates each step of a method for producing the composite wafer 10.

500 in FIG. 2 illustrates preparing an LT substrate 100. A part of the LT substrate 100 becomes the LT layer 110 in the composite wafer 10. Thus, the LT substrate 100 may also be regarded as an active substrate. The LT substrate 100 is made by cutting out a plate shape with a thickness of several hundred μm from an LT single-crystal ingot formed by a pulling up method, for example. The LT substrate 100 is subjected to a polarization treatment in which high voltage is applied along a Z-axis of the crystal, and therefore polarization along the Z-axis is caused even without external voltage.

501 in FIG. 2 illustrates implanting an ion into the LT substrate 100. By implanting an ion such as H⁺ from one surface of the LT substrate 100, an ion implantation interface 300 is formed with a thickness of several hundred nm from the one surface. Note that, the one surface is a surface that is closer to the side to be stuck in sticking.

502 in FIG. 2 illustrates forming the interposed layer 200 on the one surface of the LT substrate 100. The interposed layer 200 is formed by either a PVD method or a CVD method, for example.

503 in FIG. 2 illustrates preparing the LT substrate 400 as a supporting substrate. As in the case of the LT substrate 100, the LT substrate 400 is made by cutting out a plate shape with a thickness of several hundred μm from an LT single-crystal ingot formed by a pulling up method, for example. On the other hand, the LT substrate 400 is not subjected to the polarization treatment of the LT substrate 100. The LT substrate 400 is not substantially polarized when external voltage has not been applied.

Note that, a treatment of causing non-polarization may be positively performed on the LT substrate 400. For example, by raising a temperature of the LT substrate 400 to a temperature of a Curie point (phase transition point) or higher, the polarization caused in the LT substrate 400 is destructed. Note that, the Curie point of LT is around 607° C., and the Curie point of LN is around 1160° C.

504 in FIG. 2 illustrates sticking the LT substrate 100 and the LT substrate 400. Before sticking the LT substrate 100 and the LT substrate 400, at least either of the surfaces to be stuck is preferably subjected to an activation treatment. Note that, as in the present embodiment, when the interposed layer 200 is provided on one surface of the LT substrate 100, a sticking surface with the LT substrate 400 is a surface opposite to the LT substrate 100 in the interposed layer 200. Thus, at least either of the sticking surfaces of the interposed layer 200 and the LT substrate 400 is preferably subjected to the activation treatment. The activation treatment includes a plasma treatment, for example.

In the above-described sticking surfaces, the LT substrate 100 and the LT substrate 400 are stuck. In the present embodiment, the LT substrate 100 and the LT substrate 400 are stuck via the interposed layer 200. When at least either of the sticking surfaces has been subjected to the activation treatment, the sticking may be performed at ordinary temperature. Note that, instead of the activation treatment, in the sticking, the sticking may be performed with a high temperature of several hundred degrees (and optionally also with a high pressure).

505 in FIG. 2 illustrates delaminating the LT substrate 100. In the delaminating of the LT substrate 100, first, temperatures of the LT substrate 100, the interposed layer 200, and the LT substrate 400 which are stuck to one another are raised to, for example, about 200° C. or higher. Furthermore, the LT substrate 100 is physically delaminated at the ion implantation interface 300. In this manner, a part of the LT substrate 100 on the sticking surface side remains as the LT layer 110, and the composite wafer 10 is formed.

According to the present embodiment as above, by using substrates having thermal expansion coefficients that are equal or close to each other for the LT substrate 100 which becomes the active layer and the LT substrate 400 which becomes the supporting substrate, a warpage is less likely to be generated at the time of the thermal treatment, and the temperature can be raised to a temperature that enables delamination. Furthermore, since the LT substrate 400 which becomes the supporting substrate is not substantially polarized, a negative effect to the LT layer 110 which is the active layer can be avoided.

### Example 1

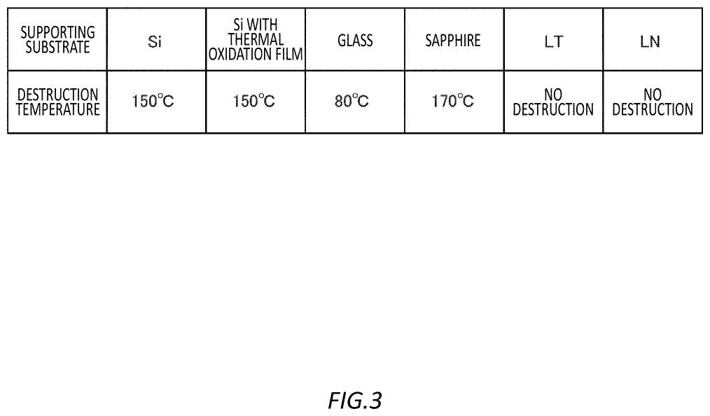

A SiO₂ film was formed for 700 nm by a PVD (sputtering) method on a 42° Y-cut LT 100 mmφ wafer (with polarization) having a thickness of 0.35 mm, and polishing was performed to 500 nm. This wafer was stuck to various supporting substrates after being subjected to a surface treatment by a plasma activation method, and the temperature was raised. FIG. 3 shows destruction temperatures at that time. A destruction occurred at a low temperature when there is a large difference in expansion coefficients, and a destruction did not occur when LT or LN which has no difference in expansion coefficients was used for the supporting substrate. The use of LT or LN as the supporting substrate is considered to be effective in terms of prevention of a crack in the substrate.

### Example 2

A SiO₂ film was formed for 700 nm by the PVD (sputtering) method on a 160° Y-cut LN 100 mmφ wafer (with polarization) having a thickness of 0.35 mm, and polishing was performed to 500 nm. This wafer was stuck to various supporting substrates after being subjected to a surface treatment by a plasma activation method, and the temperature was raised. The results were the same as Example 1.

### Example 3

H⁺ ions were implanted with 100 keV in a dose amount of 7.5e16 atoms/cm 2 into a 42° Y-cut LT 100 mmφ wafer (with polarization) having a thickness of 0.35 mm which becomes the active layer. Then, a film of SiO₂ was formed by the PVD (sputtering) method, and polishing was performed. This wafer was stuck to various supporting substrates after being subjected to a surface treatment by the plasma activation method, and the temperature was raised to 180° C. Then, delamination was performed along an implantation interface with a SiGen method (mechanical delamination method), and polishing was performed on the surface to make the thickness of LT to 500 nm, followed by a thermal treatment of 550° C. to obtain a composite wafer.

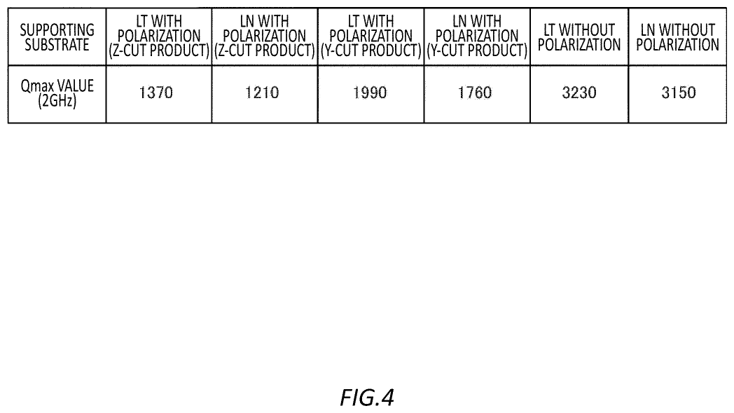

A resonator was created for these composite wafers, and a Qmax value was measured near 2 GHz. A Q value is a sharpness of a signal peak, and a value thereof is an index for measuring performance of a device. The results are shown in FIG. 4. From these results, it became clear that a supporting wafer using LT or LN without polarization has best characteristics.

### Example 4

The same experiment as Example 3 was conducted by using a 160° Y-cut LN 100 mmφ wafer (with polarization) having a thickness of 0.35 mm which becomes an active layer. The temperature was raised to 450° C. before delamination. The results showed a tendency similar to Example 3.

### Example 5

The results were almost the same even when the film of the interposed layer was formed by a CVD (chemical vapor deposition) method, or the material of the interposed layer was changed to SiON or SiN, in Example 1. It became clear that the present invention is not dependent on the film formation method or the material of the interposed layer.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the description of the claims that embodiments added with such alterations or improvements can be included in the technical scope of the present invention.

The operations, procedures, steps, stages, or the like of each process performed by a device, system, program, and method shown in the claims, embodiments, or drawings can be performed in any order as long as the order is not indicated by “prior to,” “before,” or the like and as long as the output from a previous process is not used in a later process. Even if the process flow is described using phrases such as “first” or “next” in the claims, embodiments, or drawings, it does not necessarily mean that the process must be performed in this order.

### EXPLANATION OF REFERENCES

10: composite wafer;
100: LT substrate;
110: LT layer;
200: interposed layer;
300: ion implantation interface;
400: LT substrate.

What is claimed is:

1. A composite wafer, comprising:
a supporting substrate which is either lithium tantalate or lithium niobate and is substantially not polarized;
an active layer which is either lithium tantalate or lithium niobate stuck on one surface side of the supporting substrate and is polarized; and
an interposed layer disposed on surfaces of the supporting substrate and the active layer which are stuck to each other,
wherein the interposed layer comprises at least one of SiO₂, SiON, or SiN.

2. The composite wafer according to claim 1, wherein
the interposed layer has insulation properties.

3. A method for producing a composite wafer, comprising:
preparing a supporting substrate which is either lithium tantalate or lithium niobate and is substantially not polarized;
preparing an active substrate which is either lithium tantalate or lithium niobate and is polarized;
generating an interface by implanting an ion into the active substrate;
sticking the supporting substrate and the active substrate;
raising temperatures of the supporting substrate and the active substrate which are stuck to each other; and
delaminating the active substrate at the interface, wherein
the method further comprises forming an interposed layer on at least either of surfaces of the supporting substrate and the active substrate to be stuck to each other, before the sticking,
in the sticking, the interposed layer is stuck to another of the surfaces of the supporting substrate and the active substrate to be stuck to each other, and
the interposed layer comprises at least one of SiO₂, SiON, or SiN.

4. The method for producing the composite wafer according to claim 3, wherein
the interposed layer has insulation properties.

5. The method for producing the composite wafer according to claim 3, wherein
the interposed layer is formed by either a PVD method or a CVD method.

6. A method for producing a composite wafer, comprising:
preparing a supporting substrate which is either lithium tantalate or lithium niobate and is substantially not polarized;
preparing an active substrate which is either lithium tantalate or lithium niobate and is polarized;
generating an interface by implanting an ion into the active substrate;
sticking the supporting substrate and the active substrate;
raising temperatures of the supporting substrate and the active substrate which are stuck to each other; and
delaminating the active substrate at the interface, wherein
the preparing the supporting substrate comprises non-polarizing polarization possessed by the supporting substrate in advance.

7. The method for producing the composite wafer according to claim 6, further comprising forming an interposed layer on at least either of surfaces of the supporting substrate and the active substrate to be stuck to each other, before the sticking.

8. The method for producing the composite wafer according to claim 7, wherein
the interposed layer has insulation properties.

9. The method for producing the composite wafer according to claim 7, wherein
the interposed layer comprises at least one of SiO₂, SiON, or SiN.

10. The method for producing the composite wafer according to claim 8, wherein
the interposed layer comprises at least one of SiO₂, SiON, or SiN.

11. The method for producing the composite wafer according to claim 3, further comprising subjecting at least either of surfaces of the supporting substrate and the active substrate to be stuck to each other to an activation treatment, before the sticking.

12. The method for producing the composite wafer according to claim 4, further comprising subjecting at least either of surfaces of the supporting substrate and the active substrate to be stuck to each other to an activation treatment, before the sticking.

13. The method for producing the composite wafer according to claim 5, further comprising subjecting at least either of surfaces of the supporting substrate and the active substrate to be stuck to each other to an activation treatment, before the sticking.

14. The method for producing the composite wafer according to claim 6, further comprising subjecting at least either of surfaces of the supporting substrate and the active substrate to be stuck to each other to an activation treatment, before the sticking.

15. The method for producing the composite wafer according to claim 7, further comprising subjecting at least either of surfaces of the supporting substrate and the active substrate to be stuck to each other to an activation treatment, before the sticking.

16. The method for producing the composite wafer according to claim 8, further comprising subjecting at least either of surfaces of the supporting substrate and the active substrate to be stuck to each other to an activation treatment, before the sticking.

17. The method for producing the composite wafer according to claim 9, further comprising subjecting at least either of surfaces of the supporting substrate and the active substrate to be stuck to each other to an activation treatment, before the sticking.

18. The method for producing the composite wafer according to claim 11, wherein
the activation treatment comprises a plasma treatment.
